(19) United States
(12) Patent Application Publication
(10) Pub. No.: US 2022/0244630 A1
(43) Pub. Date: Aug. 4, 2022

(54) THIN FILM-ATTACHED SUBSTRATE, MULTILAYERED REFLECTIVE FILM-ATTACHED SUBSTRATE, REFLECTIVE MASK BLANK, REFLECTIVE MASK, AND METHOD OF MANUFACTURING SEMICONDUCTOR DEVICE

(71) Applicant: HOYA CORPORATION, Tokyo (JP)

(72) Inventors: Masanori NAKAGAWA, Tokyo (JP); Takashi UCHIDA, Tokyo (JP)

(73) Assignee: HOYA CORPORATION, Tokyo (JP)

(21) Appl. No.: 17/618,858

(22) PCT Filed: Jun. 10, 2020
(86) PCT No.: PCT/JP2020/022781

§ 371 Date: Dec. 13, 2021

(30) Foreign Application Priority Data
Jun. 27, 2019 (JP) 2019-120366

(51) Int. Cl. G03F 1/24; H01L 21/027; G21K 1/06; H01L 21/033

(52) U.S. Cl. CPC G03F 1/24; H01L 21/0332; G21K 1/062; H01L 21/0274

(57) ABSTRACT

Provided is a substrate with a thin film comprising a thin film having excellent chemical resistance. A substrate with a thin film comprises a thin film on at least one of two main surfaces of the substrate. The thin film comprises chromium. When a diffracted X-ray intensity with respect to a diffraction angle 2θ is measured by an X-ray diffraction method using a CuK_{α} ray for the thin film, a peak is detected in a range where the diffraction angle 2θ is 56 degrees or more and 60 degrees or less.

### CROSS-REFERENCE TO RELATED APPLICATIONS

This application is the National Stage of International Application No. PCT/JP2020/022781, filed Jun. 10, 2020, which claims priority to Japanese Patent Application No. 2019-120366, filed Jun. 27, 2019, and the contents of which is incorporated by reference.

### TECHNICAL FIELD

The present disclosure relates to a substrate with a thin film, a substrate with a multilayer reflective film, a reflective mask blank, a reflective mask, and a method for manufacturing a semiconductor device to be used for EUV lithography.

### BACKGROUND ART

In recent years, in semiconductor industry, along with high integration of a semiconductor device, a fine pattern exceeding a transfer limit of a conventional photolithography method using ultraviolet light has been required. In order to make such fine pattern formation possible, EUV lithography, which is an exposure technique using extreme ultraviolet (hereinafter, referred to as “EUV”) light, is promising. Here, the EUV light refers to light in a wavelength band of a soft X-ray region or a vacuum ultraviolet region, and specifically, is light having a wavelength of about 0.2 to 100 nm.

A reflective mask has been proposed as a transfer mask used in this EUV lithography. In the reflective mask, a multilayer reflective film for reflecting exposure light is formed on a substrate, and a pattern forming thin film for absorbing exposure light is formed in a pattern shape on the multilayer reflective film.

The reflective mask is manufactured by forming a pattern on a pattern forming thin film by a photolithography method or the like from a reflective mask blank having a substrate, a multilayer reflective film formed on the substrate, and a pattern forming thin film formed on the multilayer reflective film.

In general, when a reflective mask is set on a mask stage of an exposure device, the reflective mask is fixed by an electrostatic chuck. Therefore, a back film (conductive back film) is formed on a back surface (surface opposite to a surface on which a multilayer reflective film or the like is formed) of an insulating reflective mask blank substrate such as a glass substrate in order to promote fixing of the substrate by an electrostatic chuck.

As an example of the substrate with a back film, Patent Document 1 describes a substrate with a back film used for manufacturing an EUV lithography reflective mask blank. Patent Document 1 describes that the back film contains chromium (Cr) and nitrogen (N), the back film has an average N concentration of 0.1 at % or more and less than 40 at %, a crystalline state of at least a surface of the back film is amorphous, the back film has a surface roughness (rms) of 0.5 nm or less, and the back film is an inclined composition film in which an N concentration in the back film changes in a thickness direction of the back film such that the N concentration on a substrate side is low and the N concentration on a surface side is high.

Patent Document 2 describes a substrate with a multilayer reflective film having a multilayer reflective film that reflects exposure light on the substrate. In addition, Patent Document 2 describes that a back film is formed in a region excluding at least a peripheral portion of the substrate on a side opposite to the multilayer reflective film across the substrate.

Patent Document 3 describes a method for correcting an error of a photolithography transfer mask. Specifically, Patent Document 3 describes that a substrate of the transfer mask is locally irradiated with a femtosecond laser pulse to modify a surface of the substrate or an inside of the substrate to correct an error of the transfer mask. Patent Document 3 exemplifies a sapphire laser (wavelength: 800 nm), a Nd-YAG laser (532 nm), and the like as a laser that generates a femtosecond laser pulse.

### PRIOR ART DOCUMENTS

### Patent Documents

Patent Document 1: WO 2008/072706 A

Patent Document 2: JP 2005-210093 A

Patent Document 3: JP 5883249 B2

### DISCLOSURE OF INVENTION

In a process of manufacturing a reflective mask blank, wet cleaning using an acidic aqueous solution (chemical solution) such as a sulfuric acid and hydrogen peroxide mixture (SPM) cleaning or wet cleaning using an alkaline aqueous solution (chemical solution) such as SC-1 cleaning is performed before a resist film is applied onto a pattern forming thin film. In addition, in the process of manufacturing a reflective mask blank, after a pattern is formed on the pattern forming thin film, wet cleaning using an acidic or alkaline aqueous solution (chemical solution) is performed in order to remove a resist pattern or the like. Furthermore, also in manufacture of a semiconductor device, wet cleaning using a chemical solution is performed in order to remove foreign substances adhering to a reflective mask during exposure. In general, since the reflective mask is repeatedly used, the cleaning is performed at least a plurality of times. Therefore, the reflective mask is required to have sufficient cleaning resistance. A chemical solution (an acidic or alkaline aqueous solution, for example, a sulfuric acid and hydrogen peroxide mixture in the case of SPM cleaning) is used for cleaning the reflective mask. Therefore, the thin film used for the reflective mask is required to have resistance to a chemical such as a chemical solution (referred to as “chemical resistance” in the present specification).

An aspect of the present disclosure is to provide a substrate with a thin film having a thin film having excellent chemical resistance. Specifically, an aspect of the present disclosure is to provide a substrate with a thin film for manufacturing a reflective mask having a back film and/or a pattern forming thin film having excellent chemical resistance.

Another aspect of the present disclosure is to provide a reflective mask blank and a reflective mask each having a back film and/or a pattern forming thin film having excellent chemical resistance.

In order to solve the above problems, the present disclosure has the following configurations.

### (Configuration 1)

Configuration 1 of the present disclosure is a substrate with a thin film comprising a thin film on at least one of two main surfaces of the substrate, in which the thin film comprises chromium, and when a diffracted X-ray intensity with respect to a diffraction angle 2θ is measured by an X-ray diffraction method using a CuK_{α} ray for the thin film, a peak is detected in a range where the diffraction angle 2θ is 56 degrees or more and 60 degrees or less.

### (Configuration 2)

Configuration 2 of the present disclosure is the substrate with a thin film according to configuration 1, in which the thin film has a peak detected in a range where the diffraction angle 2θ is 41 degrees or more and 47 degrees or less.

### (Configuration 3)

Configuration 3 of the present disclosure is the substrate with a thin film according to configuration 1 or 2, in which the thin film has no peak detected in a range where the diffraction angle 2θ is 35 degrees or more and 38 degrees or less.

### (Configuration 4)

Configuration 4 of the present disclosure is the substrate with a thin film according to any one of configurations 1 to 3, in which the thin film further comprises nitrogen.

### (Configuration 5)

Configuration 5 of the present disclosure is a substrate with a multilayer reflective film comprising a multilayer reflective film on one of two main surfaces of the substrate, in which

the substrate comprises a back film on the other main surface of the substrate,

the back film comprises chromium, and

when a diffracted X-ray intensity with respect to a diffraction angle 2θ is measured by an X-ray diffraction method using a CuK_{α} ray for the back film, a peak is detected in a range where the diffraction angle 2θ is 56 degrees or more and 60 degrees or less.

### (Configuration 6)

Configuration 6 of the present disclosure is the substrate with a multilayer reflective film according to configuration 5, in which the back film has a peak detected in a range where the diffraction angle 2θ is 41 degrees or more and 47 degrees or less.

### (Configuration 7)

Configuration 7 of the present disclosure is the substrate with a multilayer reflective film according to configuration 5 or 6, in which the back film has no peak detected in a range where the diffraction angle 2θ is 35 degrees or more and 38 degrees or less.

### (Configuration 8)

Configuration 8 of the present disclosure is the substrate with a multilayer reflective film according to any one of configurations 5 to 7, in which the back film further comprises nitrogen.

### (Configuration 9)

Configuration 9 of the present disclosure is a reflective mask blank comprising a structure in which a multilayer reflective film and a pattern forming thin film are layered in this order on one of two main surfaces of the substrate, in which

the substrate comprises a back film on the other main surface of the substrate,

the back film comprises chromium, and

when a diffracted X-ray intensity with respect to a diffraction angle 2θ is measured by an X-ray diffraction method using a CuK_{α} ray for the back film, a peak is detected in a range where the diffraction angle 2θ is 56 degrees or more and 60 degrees or less.

### (Configuration 10)

Configuration 10 of the present disclosure is the reflective mask blank according to configuration 9, in which the back film has a peak detected in a range where the diffraction angle 2θ is 41 degrees or more and 47 degrees or less.

### (Configuration 11)

Configuration 11 of the present disclosure is the reflective mask blank according to configuration 9 or 10, in which the back film has no peak detected in a range where the diffraction angle 2θ is 35 degrees or more and 38 degrees or less.

### (Configuration 12)

Configuration 12 of the present disclosure is the reflective mask blank according to any one of configurations 9 to 11, in which the back film further comprises nitrogen.

### (Configuration 13)

Configuration 13 of the present disclosure is a reflective mask comprising a transfer pattern formed on the pattern forming thin film of the reflective mask blank according to any one of configurations 9 to 12.

### (Configuration 14)

Configuration 14 of the present disclosure is a method for manufacturing a semiconductor device, the method comprising exposing and transferring a transfer pattern onto a resist film on a semiconductor substrate using the reflective mask according to configuration 13.

The present disclosure can provide a substrate with a thin film having a thin film having excellent chemical resistance. Specifically, the present disclosure can provide a substrate with a thin film for manufacturing a reflective mask having a back film and/or a pattern forming thin film having excellent chemical resistance.

In addition, the present disclosure can provide a reflective mask blank and a reflective mask having a back film and/or a pattern forming thin film having excellent chemical resistance.

### BRIEF DESCRIPTION OF DRAWINGS

FIG. 1 is a schematic cross-sectional diagram illustrating an example of a configuration of a substrate with a back film, which is an embodiment of a substrate with a thin film of the present disclosure.

FIG. 2 is a schematic cross-sectional diagram illustrating an example of a configuration of a substrate with a multilayer reflective film (substrate with a back film) according to an embodiment of the present disclosure.

FIG. 3 is a schematic cross-sectional diagram illustrating an example of a configuration of a reflective mask blank according to an embodiment of the present disclosure.

FIG. 4 is a schematic cross-sectional diagram illustrating an example of a reflective mask according to an embodiment of the present disclosure.

FIG. 5 is a schematic cross-sectional diagram illustrating another example of the configuration of the reflective mask blank according to an embodiment of the present disclosure.

FIGS. 6A to 6D are process diagrams illustrating a process of preparing a reflective mask from a reflective mask blank in a schematic cross-sectional diagram.

FIG. 7 is a diagram (diffracted X-ray spectrum) illustrating a diffracted X-ray intensity (counts/second) with respect to an X-ray diffraction angle (2θ) for Example 1 and Comparative Example 1.

FIG. 8 is a diagram (diffracted X-ray spectrum) illustrating a diffracted X-ray intensity (counts/second) with respect to an X-ray diffraction angle (2θ) for Comparative Example 2.

### DESCRIPTION OF EMBODIMENTS

Hereinafter, an embodiment of the present disclosure will be specifically described with reference to the drawings. Note that the following embodiment is one mode for embodying the present disclosure and does not limit the present disclosure within the scope thereof

The present embodiment is a substrate with a thin film including a thin film on at least one of two main surfaces of the substrate. A predetermined thin film according to the present embodiment has excellent chemical resistance. Therefore, the substrate with a thin film according to the present embodiment can be used for an application in which repeated cleaning using a chemical such as a chemical solution is required. As such an application, a reflective mask to be used for EUV lithography can be exemplified. The substrate with a thin film according to the present embodiment can be preferably used as a substrate with a thin film for manufacturing a reflective mask.

Hereinafter, the present embodiment will be described by exemplifying the substrate with a thin film for manufacturing a reflective mask. However, the substrate with a thin film of the present disclosure is not limited to the substrate with a thin film for manufacturing a reflective mask.

The present embodiment is a substrate with a thin film including a predetermined thin film containing chromium and exhibiting predetermined crystallinity on at least one of two main surfaces of a mask blank substrate (also simply referred to as a “substrate”). In the present specification, the predetermined thin film containing chromium and exhibiting predetermined crystallinity, used in the present embodiment, is referred to as a “predetermined thin film”. Note that, for the sake of explanation, a similar thin film (for example, a thin film in Comparative Example) corresponding to the predetermined thin film according to the present embodiment may be referred to as a “predetermined thin film”.

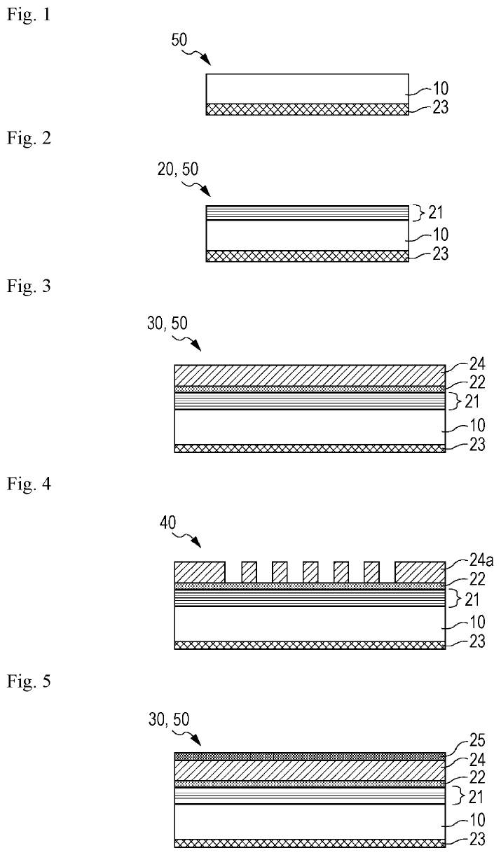

FIG. 1 is a schematic diagram illustrating an example of a substrate with a back film 50, which is an example of the substrate with a thin film according to the present embodiment. In the example illustrated in FIG. 1, a back film 23 of the substrate with a back film 50 is the predetermined thin film.

FIG. 2 is a schematic diagram illustrating an example of a substrate with a multilayer reflective film 20, which is an example of the substrate with a thin film according to the present embodiment. In the example illustrated in FIG. 2, the back film 23 of the substrate with a back film 50 is the predetermined thin film. Note that the substrate with a multilayer reflective film 20 illustrated in FIG. 2 includes a multilayer reflective film 21.

FIG. 3 is a schematic diagram illustrating an example of a reflective mask blank 30, which is an example of the substrate with a thin film according to the present embodiment. In the example illustrated in FIG. 3, a back film 23 and/or a pattern forming thin film 24 of the reflective mask blank 30 is the predetermined thin film. Note that the reflective mask blank 30 illustrated in FIG. 3 includes a multilayer reflective film 21.

In the present specification, out of main surfaces of a mask blank substrate 10, a main surface on which a back film 23 (also be referred to as a “conductive back film” or simply a “conductive film”) is formed may be referred to as a “back surface”, a “back main surface”, or a “second main surface”. In addition, in the present specification, a main surface (also simply referred to as a “surface”) of the substrate with a back film 50 on which the back film 23 is not formed may be referred to as a “front main surface” (or a “first main surface”). The multilayer reflective film 21 in which a high refractive index layer and a low refractive index layer are alternately layered is formed on the front main surface of the mask blank substrate 10.

In the present specification, the expression “including (having) a predetermined thin film on a main surface of the mask blank substrate 10” means that the predetermined thin film is disposed in contact with a main surface of the mask blank substrate 10, and also means that there is another film between the mask blank substrate 10 and the predetermined thin film. The same applies to films other than the predetermined thin film. For example, the expression “having a film B on a film A” means that the film A and the film B are disposed so as to be in direct contact with each other, and also means that there is another film between the film A and the film B. In addition, in the present specification, for example, the expression “the film A is disposed in contact with a surface of the film B” means that the film A and the film B are disposed in direct contact with each other without another film interposed between the film A and the film B.

Next, surface roughness (Rms), which is a parameter indicating a surface state of the mask blank substrate 10 and a surface state of a surface of a thin film constituting the reflective mask blank 30 or the like, will be described.

Root mean square (Rms) as a representative index of surface roughness is root mean square roughness, which is a square root of a value obtained by averaging squares of deviations from a mean line to a measurement curve. Rms is expressed by the following formula (1).

$$\begin{matrix}[ Mathematical formula 1 ] & \\ Rms = \sqrt{\frac{1}{l} {\int }_{0}^{1} {Z}^{2} ( x ) d x} & ( 1 )\end{matrix}$$

In formula (1), l represents a reference length, and Z represents a height from a mean line to a measurement curve.

Rms is conventionally used to manage the surface roughness of the mask blank substrate 10. By using Rms, the surface roughness can be grasped numerically.

[Substrate with a Thin Film]

Next, a predetermined thin film that can be used for the substrate with a thin film according to the present embodiment will be described.

The substrate with a thin film according to the present embodiment includes the predetermined thin film having predetermined crystallinity on at least one of two main surfaces of the substrate 10.

FIG. 1 is a schematic diagram illustrating an example of the substrate with a back film 50, which is an example of the substrate with a thin film according to the present embodiment. The substrate with a back film 50 according to the present embodiment has a structure in which the back film 23 is formed on a back main surface of the mask blank substrate 10. In the example of the substrate with a back film 50 illustrated in FIG. 1, the back film 23 is the predetermined thin film. Note that in the present specification, the substrate with a back film 50 is one in which the back film 23 is formed on at least a back main surface of the mask blank substrate 10, and the substrate with a back film 50 also includes one in which the multilayer reflective film 21 is formed on the other main surface (the substrate with a multilayer reflective film 20), one in which the pattern forming thin film 24 is further formed (the reflective mask blank 30), and the like.

FIG. 2 illustrates the substrate with a multilayer reflective film 20 according to the present embodiment in which the back film 23 is formed on a back main surface. The substrate with a multilayer reflective film 20 illustrated in FIG. 2 includes the back film 23 on the back main surface, and thus is a type of the substrate with a back film 50. In the example of the substrate with a multilayer reflective film 20 (substrate with a back film 50) according to the present embodiment illustrated in FIG. 2, the back film 23 is the predetermined thin film. Therefore, the substrate with a multilayer reflective film 20 (substrate with a back film 50) illustrated in FIG. 2 is a type of the substrate with a thin film according to the present embodiment.

FIG. 3 is a schematic diagram illustrating an example of the reflective mask blank 30 according to the present embodiment. The reflective mask blank 30 of FIG. 3 includes the multilayer reflective film 21, a protective film 22, and the pattern forming thin film 24 on a front main surface of the mask blank substrate 10. In addition, the reflective mask blank 30 of FIG. 3 includes the back film 23 on a back main surface thereof. In the example illustrated in FIG. 3, at least one of the back film 23 and the pattern forming thin film 24 of the reflective mask blank 30 is the predetermined thin film. Therefore, the reflective mask blank 30 illustrated in FIG. 3 is a type of the substrate with a thin film according to the present embodiment.

FIG. 5 is a schematic diagram illustrating another example of the reflective mask blank 30 according to the present embodiment. The reflective mask blank 30 illustrated in FIG. 5 includes the multilayer reflective film 21, the pattern forming thin film 24, the protective film 22 formed between the multilayer reflective film 21 and the pattern forming thin film 24, and an etching mask film 25 formed on a surface of the pattern forming thin film 24. The reflective mask blank 30 according to the present embodiment includes the back film 23 on a back main surface thereof. In the example illustrated in FIG. 5, at least one of the back film 23, the pattern forming thin film 24, and the etching mask film 25 of the reflective mask blank 30 is the predetermined thin film. Therefore, the reflective mask blank 30 illustrated in FIG. 5 is a type of the substrate with a thin film according to the present embodiment. Note that when the reflective mask blank 30 having the etching mask film 25 is used, as described later, the etching mask film 25 may be peeled off after a transfer pattern is formed on the pattern forming thin film 24. In addition, in the reflective mask blank 30 in which the etching mask film 25 is not formed, the pattern forming thin film 24 may have a stack formed of a plurality of layers, and materials constituting the plurality of layers may have etching characteristics different from each other to form the pattern forming thin film 24 having an etching mask function.

### [Predetermined Thin Film]

Next, the predetermined thin film used for the substrate with a thin film according to the present embodiment will be described.

The predetermined thin film of the substrate with a thin film according to the present embodiment contains chromium. The predetermined thin film preferably contains nitrogen. By inclusion of chromium and nitrogen in the thin film, the chemical resistance of the predetermined thin film can be further enhanced. In addition, the predetermined thin film has predetermined crystallinity, and therefore exhibits a unique diffracted X-ray spectrum (hereinafter, such a diffracted X-ray spectrum may be referred to as a “predetermined diffracted X-ray spectrum”) as described below.

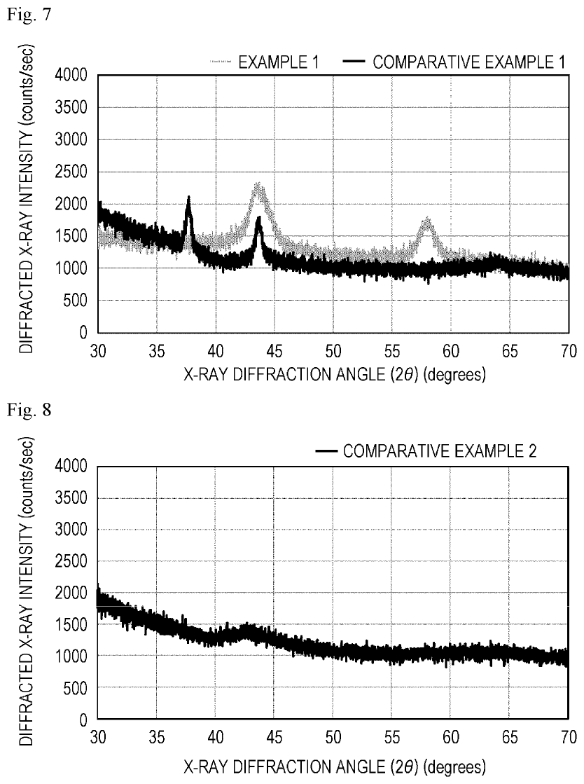

When a diffracted X-ray intensity with respect to a diffraction angle 2θ is measured by an X-ray diffraction method using a CuK_{α} ray for the predetermined thin film of the substrate with a thin film according to the present embodiment, a peak is detected in a range where the diffraction angle 2θ is 56 degrees or more and 60 degrees or less. FIG. 7 illustrates a diffracted X-ray spectrum (diffracted X-ray intensity with respect to the diffraction angle 2θ) obtained by measuring a diffracted X-ray intensity for the predetermined thin film according to the present embodiment. Example 1 illustrated in FIG. 7 is the diffracted X-ray spectrum of the predetermined thin film according to the present embodiment. As illustrated in FIG. 7, in the diffracted X-ray spectrum of Example 1, a peak is detected in a range where the diffraction angle 2θ is 56 degrees or more and 60 degrees or less. Meanwhile, as illustrated in FIG. 7, in Comparative Example 1 having poor chemical resistance, no peak is detected in a range where the diffraction angle 2θ is 56 degrees or more and 60 degrees or less.

In the present specification, a peak detected by an X-ray diffraction method is a peak obtained by illustrating measurement data of a diffracted X-ray intensity with respect to the diffraction angle 2θ using a CuK_{α} ray, and can be defined as a peak in which the height of the peak obtained by subtracting a background from the measurement data (diffracted X-ray spectrum) is twice or more the magnitude of a background noise (noise width) around the peak. The diffraction angle 2θ of the peak can be defined as a diffraction angle 2θ indicating a maximum value of the peak obtained by subtracting a background from the measurement data.

When a diffracted X-ray intensity with respect to the diffraction angle 2θ is measured by an X-ray diffraction method using a CuK_{α} ray for the predetermined thin film of the substrate with a thin film according to the present embodiment, a peak is detected in a range where the diffraction angle 2θ is 56 degrees or more and 60 degrees or less. Note that it is presumed that this peak corresponds to a peak of a (112) plane of Cr₂N, but the present disclosure is not bound by this presumption. The present inventors have found that a chromium-containing thin film having a crystal structure in which a peak is detected in a range where the diffraction angle 2θ is 56 degrees or more and 60 degrees or less has excellent chemical resistance, and have reached the present disclosure. Therefore, according to the present embodiment, a substrate with a thin film having a thin film having excellent chemical resistance can be obtained. In addition, for example, when a reflective mask 40 is manufactured using the substrate with a thin film according to the present embodiment, even if the reflective mask 40 is repeatedly cleaned using a chemical such as a chemical solution, deterioration of the thin film of the reflective mask 40 can be suppressed. According to the present embodiment, in particular, it is possible to increase resistance to SPM cleaning of the predetermined thin film.

In the predetermined thin film of the substrate with a thin film according to the present embodiment, a peak is preferably detected in a range where the diffraction angle 2θ is 41 degrees or more and 47 degrees or less. As illustrated in FIG. 7, in the diffracted X-ray spectrum of Example 1, a peak is detected in a range where the diffraction angle 2θ is 41 degrees or more and 47 degrees or less. Note that it is presumed that this peak corresponds to a peak of a (111) plane of Cr₂N or a (200) plane of CrN, but the present disclosure is not bound by this presumption. A peak is detected in a range where the diffraction angle 2θ is 41 degrees or more and 47 degrees or less in addition to a range where the diffraction angle 2θ is 56 degrees or more and 60 degrees or less. As a result, it is possible to more reliably obtain a substrate with a thin film having a thin film having excellent chemical resistance.

In the predetermined thin film of the substrate with a thin film according to the present embodiment, preferably, no peak is detected in a range where the diffraction angle 2θ is 35 degrees or more and 38 degrees or less. As illustrated in FIG. 7, in the diffracted X-ray spectrum of Example 1, no peak is detected in a range where the diffraction angle 2θ is 35 degrees or more and 38 degrees or less. Note that it is presumed that a peak in this range of the diffraction angle 2θ corresponds to a peak of a (111) plane of CrN, but the present disclosure is not bound by this presumption. Meanwhile, as illustrated in FIG. 7, in Comparative Example 1 having poor chemical resistance, a peak is detected in a range where the diffraction angle 2θ is 35 degrees or more and 38 degrees or less. The present inventors have found that a chromium-containing thin film having a crystal structure in which no peak is detected in a range where the diffraction angle 2θ is 35 degrees or more and 38 degrees or less has excellent chemical resistance. According to the present embodiment, a peak is detected in a range where the diffraction angle 2θ is 56 degrees or more and 60 degrees or less, and no peak is detected in a range where the diffraction angle 2θ is 35 degrees or more and 38 degrees or less. As a result, it is possible to more reliably obtain a substrate with a thin film having a thin film having excellent chemical resistance.

The predetermined thin film of the substrate with a thin film according to the present embodiment preferably contains nitrogen. By inclusion of chromium and nitrogen in the predetermined thin film, the chemical resistance of the predetermined thin film can be further enhanced. In addition, in order to further enhance the chemical resistance of the predetermined thin film, the predetermined thin film of the substrate with a thin film according to the present embodiment preferably contains only chromium and nitrogen except for impurities that are inevitably mixed. Note that, in the present specification, even when it is simply described that “the thin film contains only chromium and nitrogen”, it means that the thin film can contain impurities that are inevitably mixed in addition to chromium and nitrogen. As described below, the crystal structure of the predetermined thin film changes depending on the nitrogen content of the predetermined thin film.

When the predetermined thin film containing chromium and nitrogen contains a small amount of nitrogen (for example, when the content of nitrogen is 15 atomic % or less), there arises a problem that the predetermined thin film has an amorphous crystal structure and has low chemical resistance. When this predetermined thin film is measured by an X-ray diffraction method, no peak is observed. For example, FIG. 8 illustrates a diffracted X-ray spectrum of a predetermined thin film (back film 23) containing only chromium and nitrogen and having a nitrogen content of about 10 atomic % in Comparative Example 2. As illustrated in FIG. 8, in the predetermined thin film of Comparative Example 2, no peak is detected in a range where the diffraction angle 2θ is 56 degrees or more and 60 degrees or less. Note that in Comparative Example 2, a broad peak-like one is detected in a range where the diffraction angle 2θ is 41 degrees or more and 47 degrees or less. However, in the broad peak-like one of Comparative Example 2, the height of the peak obtained by subtracting a background from measurement data is not twice or more the magnitude of a background noise (noise width) around the peak. Therefore, the broad peak-like one of Comparative Example 2 cannot be recognized as a peak in the present specification.

Meanwhile, when the predetermined thin film containing chromium and nitrogen contains a large amount of nitrogen (for example, when the content of nitrogen is 40 atomic % or more,), the crystal structure of the predetermined thin film exhibits high crystallinity. When this thin film is measured by an X-ray diffraction method, a peak caused by a CrN (111) plane around the diffraction angle 2θ=38 degrees and a peak caused by a CrN (200) plane around the diffraction angle 2θ=44 degrees are observed. However, when the thin film contains a large amount of nitrogen, conductivity decreases. Therefore, it is difficult to use the thin film as the back film 23 of the reflective mask 40. For example, FIG. 7 illustrates a diffracted X-ray spectrum of a predetermined thin film (back film 23) containing only chromium and nitrogen and having a nitrogen content of 45 atomic % in Comparative Example 1. In this diffracted X-ray spectrum, a peak caused by a CrN (111) plane around the diffraction angle 2θ=38 degrees and a peak caused by a CrN (200) plane around the diffraction angle 2θ=44 degrees are observed. However, as described above, the predetermined thin film of Comparative Example 1 has poorer chemical resistance than the predetermined thin film of Example 1. Furthermore, since the predetermined thin film of Comparative Example 1 contains a large amount of nitrogen, the conductivity (sheet resistance) of the thin film decreases. Therefore, it is difficult to use the predetermined thin film of Comparative Example 1 as the back film 23 of the reflective mask 40 for an electrostatic chuck.

As described above, in a case where the thin film containing chromium and nitrogen has a crystal structure in which a peak is detected in a range where the diffraction angle 2θ is 56 degrees or more and 60 degrees or less when being measured by an X-ray diffraction method, chemical resistance, particularly resistance to SPM cleaning is high, and an appropriate conductivity can be obtained as the back film 23 of the reflective mask 40.

As a method for forming the predetermined thin film according to the present embodiment, any known method can be used as long as necessary characteristics can be obtained. As the method for forming the predetermined thin film, it is common to use a sputtering method such as a DC magnetron sputtering method, an RF sputtering method, or an ion beam sputtering method. In order to more reliably obtain necessary characteristics, a reactive sputtering method can be used. When the predetermined thin film contains chromium and nitrogen, by introducing a nitrogen gas using a chromium target and forming a film in a nitrogen atmosphere by sputtering, the predetermined thin film containing chromium and nitrogen can be formed. Note that by controlling a flow rate of a nitrogen gas introduced during sputtering, the predetermined thin film having a predetermined diffracted X-ray spectrum can be formed. In addition to the nitrogen gas, an inert gas such as an argon gas can be used in combination.

In the method for forming the predetermined thin film, specifically, the film is preferably formed while the substrate 10 is rotated on a horizontal plane with a film formation surface of the substrate 10 for forming the predetermined thin film facing upward. At this time, the film is preferably formed at a position where a central axis of the substrate 10 and a straight line passing through the center of a sputtering target and parallel to the central axis of the substrate 10 are shifted from each other. That is, the predetermined thin film is preferably formed by inclining the sputtering target at a predetermined angle with respect to the film formation surface. The sputtering target and the substrate 10 are disposed in this manner, and the facing sputtering target is sputtered. As a result, the predetermined thin film can be formed. The predetermined angle is preferably an angle at which an inclination angle of the sputtering target is 5 degrees or more and 30 degrees or less. In addition, a gas pressure during sputtering film formation is preferably 0.03 Pa or more and 0.1 Pa or less.

Note that there is no unique relationship between the fact that the predetermined thin film containing chromium and nitrogen has a peak in the predetermined range of the diffraction angle 2θ of the diffracted X-ray spectrum defined above and the nitrogen content of the predetermined thin film. Film forming conditions under which a peak is obtained in a predetermined range of the diffraction angle 2θ are different depending on a film forming device for forming the thin film. It is important that the predetermined thin film has a peak in a predetermined range of the diffraction angle 2θ of the diffracted X-ray spectrum. It is not important to control the nitrogen content of the predetermined thin film. If there is an index in a predetermined range of the diffraction angle 2θ in which a peak should be present in a diffracted X-ray spectrum required for the predetermined thin film, by repeatedly forming the thin film by adjusting film forming conditions of the film forming device, and acquiring and verifying a diffracted X-ray spectrum, the predetermined thin film can be obtained. This work itself is not difficult.

[Substrate with a Back Film 50]

Next, the substrate with a thin film according to the embodiment will be specifically described by exemplifying the substrate with a back film 50 for manufacturing the reflective mask 40. First, the mask blank substrate 10 (also simply referred to as the “substrate 10”) used for the substrate with a back film 50 will be described.

### <Mask Blank Substrate 10>

As the mask blank substrate 10, one having a low thermal expansion coefficient in a range of 0±5 ppb/° C. is preferably used in order to prevent distortion of a transfer pattern (a thin film pattern 24a of the pattern forming thin film 24 described later) due to heat during exposure with EUV light. Examples of a usable material having a low thermal expansion coefficient in this range include SiO₂-TiO₂-based glass, multicomponent glass ceramics, and the like.

A first main surface of the substrate 10 on a side where a transfer pattern is formed has been subjected to a surface treatment so as to have high flatness from a viewpoint of obtaining at least pattern transfer accuracy and position accuracy. In a case of EUV exposure, in an area of 132 mm×132 mm of the first main surface of the substrate 10 on a side where a transfer pattern is formed, flatness is preferably 0.1 μm or less, more preferably 0.05 μm or less, and still more preferably 0.03 μm or less. In addition, a second main surface opposite to the first main surface is a surface to be electrostatically chucked when set in an exposure device. In an area of 132 mm×132 mm of the second main surface, flatness is preferably 0.1 μm or less, more preferably 0.05 μm or less, and still more preferably 0.03 μm or less. Note that in an area of 142 mm×142 mm of a second main surface of the reflective mask blank 30, flatness is preferably 1 μm or less, more preferably 0.5 μm or less, and still more preferably 0.3 μm or less.

In addition, high surface smoothness of the substrate 10 is also an extremely important item. Surface roughness of a first main surface on which a thin film pattern 24a of the pattern forming thin film 24 for transfer is formed is preferably 0.1 nm or less in terms of root mean square roughness (RMS). Note that the surface smoothness can be measured with an atomic force microscope.

Furthermore, the substrate 10 preferably has high rigidity in order to prevent deformation due to a film stress applied to a film (such as the multilayer reflective film 21) formed on the substrate 10. In particular, the substrate 10 preferably has a high Young's modulus of 65 GPa or more.

<Substrate with a Multilayer Reflective Film 20>

Next, the substrate with a multilayer reflective film 20 according to the present embodiment will be described below. The substrate with a multilayer reflective film 20 according to the present embodiment includes the multilayer reflective film 21 on one of two main surfaces of the substrate 10, and includes the back film 23 including the predetermined thin film on the other main surface of the substrate 10 (see FIG. 2).

Note that in the present specification, as illustrated in FIG. 2, one having a structure in which the multilayer reflective film 21 is formed on the substrate with a back film 50 (substrate with a thin film) according to the present embodiment is referred to as the substrate with a multilayer reflective film 20 according to the present embodiment.

### <Multilayer Reflective Film 21>

In the substrate with a multilayer reflective film 20 according to the present embodiment, the multilayer reflective film 21 in which a high refractive index layer and a low refractive index layer are alternately layered is formed on a main surface opposite to a side on which the back film 23 is formed. The substrate with a multilayer reflective film 20 according to the present embodiment can reflect EUV light having a predetermined wavelength by including the predetermined multilayer reflective film 21.

Note that in the present embodiment, the multilayer reflective film 21 can be formed before the back film 23 is formed. In addition, the back film 23 may be formed as illustrated in FIG. 1, and then the multilayer reflective film 21 may be formed as illustrated in FIG. 2.

The multilayer reflective film 21 provides a function of reflecting EUV light in the reflective mask 40. The multilayer reflective film 21 has a structure of a multilayer film in which layers mainly containing elements having different refractive indexes are periodically layered.

In general, as the multilayer reflective film 21, a multilayer film in which a thin film (high refractive index layer) of a light element that is a high refractive index material or a compound of the light element and a thin film (low refractive index layer) of a heavy element that is a low refractive index material or a compound of the heavy element are alternately layered for about 40 to 60 periods. The multilayer film may be formed by counting, as one period, a stack of a high refractive index layer and a low refractive index layer in which the high refractive index layer and the low refractive index layer are layered in this order from the substrate 10 and building up the stack for a plurality of periods. In addition, the multilayer film may be formed by counting, as one period, a stack of a low refractive index layer and a high refractive index layer in which the low refractive index layer and the high refractive index layer are layered in this order from the substrate 10 and building up the stack for a plurality of periods. Note that a layer on the outermost surface of the multilayer reflective film 21 (that is, a surface layer of the multilayer reflective film 21 on a side opposite to the substrate 10) is preferably a high refractive index layer. In the multilayer film described above, when a stack (high refractive index layer and low refractive index layer) in which a high refractive index layer and a low refractive index layer are layered in this order on the substrate 10 is counted as one period and the stack is built up for a plurality of periods, the uppermost layer is a low refractive index layer. Since the low refractive index layer on the outermost surface of the multilayer reflective film 21 is easily oxidized, a reflectance of the multilayer reflective film 21 decreases. In order to avoid a decrease in the reflectance, it is preferable to further form a high refractive index layer on the low refractive index layer that is the uppermost layer to form the multilayer reflective film 21. Meanwhile, in the multilayer film described above, when a stack (low refractive index layer and high refractive index layer) in which a low refractive index layer and a high refractive index layer are layered in this order on the substrate 10 is counted as one period and the stack is built up for a plurality of periods, the uppermost layer is a high refractive index layer. In this case, there is no need to further form a high refractive index layer.

In the present embodiment, a layer containing silicon (Si) is adopted as the high refractive index layer. As a material containing Si, in addition to a Si simple substance, a Si compound containing Si and boron (B), carbon (C), nitrogen (N), and/or oxygen (O) can be used. By using a layer containing Si as the high refractive index layer, the reflective mask 40 for EUV lithography having an excellent reflectance for EUV light can be obtained. In addition, in the present embodiment, a glass substrate is preferably used as the substrate 10. Si also has excellent adhesion to the glass substrate. In addition, as the low refractive index layer, a metal simple substance selected from molybdenum (Mo), ruthenium (Ru), rhodium (Rh), and platinum (Pt), or an alloy thereof is used. For example, as the multilayer reflective film 21 for EUV light having a wavelength of 13 nm to 14 nm, a Mo/Si periodic layered film in which a Mo film and a Si film are alternately layered for about 40 to 60 periods is preferably used. Note that the high refractive index layer that is the uppermost layer of the multilayer reflective film 21 can be formed using silicon (Si), and a silicon oxide layer containing silicon and oxygen can be formed between the uppermost layer (Si) and the Ru-based protective film 22. By forming the silicon oxide layer, cleaning resistance of the reflective mask 40 can be improved.

The above-described multilayer reflective film 21 alone usually has a reflectance of 65% or more, and an upper limit of the reflectance is usually 73%. Note that the thickness and period of each constituent layer of the multilayer reflective film 21 can be appropriately selected depending on an exposure wavelength, and can be selected so as to satisfy, for example, the Bragg's reflection law. In the multilayer reflective film 21, there are a plurality of high refractive index layers and a plurality of low refractive index layers. The plurality of high refractive index layers does not need to have the same thickness, and the plurality of low refractive index layers does not need to have the same thickness. In addition, the film thickness of the Si layer that is the outermost surface of the multilayer reflective film 21 can be adjusted in a range that does not lower the reflectance. The film thickness of the Si (high refractive index layer) of the outermost surface can be 3 nm to 10 nm.

A method for forming the multilayer reflective film 21 is known. For example, the multilayer reflective film 21 can be formed by forming each layer of the multilayer reflective film 21 by an ion beam sputtering method. In the case of the above-described Mo/Si periodic multilayer film, for example, by an ion beam sputtering method, first, a Si film having a thickness of about 4 nm is formed on the substrate 10 using an Si target, and then a Mo film having a thickness of about 3 nm is formed using a Mo target. This stack of a Si film and a Mo film is counted as one period, and the stack is built up for 40 to 60 periods to form the multilayer reflective film 21 (the layer on the outermost surface is a Si layer). In addition, when the multilayer reflective film 21 is formed, the multilayer reflective film 21 is preferably formed by supplying krypton (Kr) ion particles from an ion source and performing ion beam sputtering.

### <Protective Film 22>

The substrate with a multilayer reflective film 20 according to the present embodiment preferably further includes the protective film 22 disposed in contact with a surface of the multilayer reflective film 21 on a side opposite to the mask blank substrate 10.

The protective film 22 is formed on the multilayer reflective film 21 in order to protect the multilayer reflective film 21 from dry etching and cleaning in a process of manufacturing the reflective mask 40 described later. In addition, when a black defect of a transfer pattern (the thin film pattern 24a described later) using an electron beam (EB) is corrected, the multilayer reflective film 21 can be protected by the protective film 22. The protective film 22 can have a stack of three or more layers. For example, the protective film 22 can have a structure in which the lowermost layer and the uppermost layer of the protective film 22 are layers containing a substance containing Ru, and a metal other than Ru or an alloy of a metal other than Ru is interposed between the lowermost layer and the uppermost layer. A material of the protective film 22 includes, for example, a material containing ruthenium as a main component. As the material containing ruthenium as a main component, a Ru metal simple substance and a Ru alloy containing Ru and a metal such as titanium (Ti), niobium (Nb), molybdenum (Mo), zirconium (Zr), yttrium (Y), boron (B), lanthanum (La), cobalt (Co), and/or rhenium (Re) can be used. In addition, these materials of the protective film 22 can further contain nitrogen. The protective film 22 is effective for patterning the pattern forming thin film 24 by dry etching with a Cl-based gas.

When a Ru alloy is used as the material of the protective film 22, a Ru content ratio of the Ru alloy is 50 atomic % or more and less than 100 atomic %, preferably 80 atomic % or more and less than 100 atomic %, and more preferably 95 atomic % or more and less than 100 atomic %. In particular, when the Ru content ratio of the Ru alloy is 95 atomic % or more and less than 100 atomic %, the reflectance for EUV light can be secured sufficiently while diffusion of an element (silicon) constituting the multilayer reflective film 21 to the protective film 22 is suppressed. Furthermore, this protective film 22 can have mask cleaning resistance, an etching stopper function when the pattern forming thin film 24 is etched, and a protective function for preventing a temporal change of the multilayer reflective film 21.

In a case of EUV lithography, since there are few substances that are transparent to exposure light, it is not technically easy to apply an EUV pellicle that prevents a foreign matter from adhering to a mask pattern surface. For this reason, pellicle-less operation without using a pellicle has been the mainstream. In addition, in the case of EUV lithography, exposure contamination such as carbon film deposition on a mask or an oxide film growth due to EUV exposure occurs. Therefore, at a stage where the EUV reflective mask 40 is used for manufacturing a semiconductor device, it is necessary to frequently clean the mask to remove foreign matters and contamination on the mask. Therefore, the EUV reflective mask 40 is required to have extraordinary mask cleaning resistance as compared with a transmissive mask for optical lithography. With use of the Ru-based protective film 22 containing Ti, cleaning resistance to a cleaning liquid such as sulfuric acid, a sulfuric acid and hydrogen peroxide mixture (SPM), ammonia, ammonia peroxide (APM), OH radical cleaning water, or ozone water having a concentration of 10 ppm or less can be particularly high. Therefore, it is possible to satisfy the requirement of the mask cleaning resistance for the EUV reflective mask 40.

The thickness of the protective film 22 is not particularly limited as long as the function of the protective film 22 can be achieved. The thickness of the protective film 22 is preferably 1.0 nm to 8.0 nm, and more preferably 1.5 nm to 6.0 nm from a viewpoint of the reflectance for EUV light.

As a method for forming the protective film 22, it is possible to adopt a method similar to a known film forming method without any particular limitation. Specific examples of the method for forming the protective film 22 include a sputtering method and an ion beam sputtering method.

The substrate with a multilayer reflective film 20 according to the present embodiment can have a base film in contact with a main surface of the substrate 10. The base film is a thin film formed between the substrate 10 and the multilayer reflective film 21. By having the base film, it is possible to prevent charge-up at the time of mask pattern defect inspection using an electron beam, to reduce phase defects of the multilayer reflective film 21, and to obtain high surface smoothness.

As a material of the base film, a material containing ruthenium or tantalum as a main component is preferably used. Specifically, as the material of the base film, for example, a Ru metal simple substance, a Ta metal simple substance, a Ru alloy, or a Ta alloy can be used. As the Ru alloy and the Ta alloy, an alloy containing Ru and/or Ta and a metal such as titanium (Ti), niobium (Nb), molybdenum (Mo), zirconium (Zr), yttrium (Y), boron (B), lanthanum (La), cobalt (Co), and/or rhenium (Re) can be used. The film thickness of the base film can be, for example, in a range of 1 nm to 10 nm.

<Substrate with a Back Film 50>

Next, the substrate with a back film 50 according to the present embodiment will be described. On a back main surface of the substrate 10 (a main surface opposite to a main surface on which the multilayer reflective film 21 is formed), a conductive film (back film 23) for an electrostatic chuck is generally formed. In the substrate with a back film 50 according to the present embodiment, the back film 23 includes the predetermined thin film.

In the substrate with a multilayer reflective film 20 illustrated in FIG. 2, the back film 23 having the predetermined thin film is formed on a surface of the substrate 10 opposite to a surface in contact with the multilayer reflective film 21. As a result, the substrate with a back film 50 according to the present embodiment as illustrated in FIG. 2 can be obtained. Note that the substrate with a back film 50 according to the present embodiment does not necessarily have the multilayer reflective film 21. As illustrated in FIG. 1, by forming the predetermined back film 23 on one main surface of the mask blank substrate 10, the substrate with a back film 50 according to the present embodiment can also be obtained.

An electrical characteristic required for the back film 23 having conductivity for an electrostatic chuck is usually 150 Ω/A (Ω/square) or less, and preferably 100 Ω/A or less. The thickness of the back film 23 is not particularly limited as long as a function of the back film 23 for an electrostatic chuck is fulfilled, but is usually 10 nm to 200 nm. In addition, the back film 23 further has a function of stress adjustment on a side of the back main surface of the reflective mask blank 30. The back film 23 is adjusted such that the flat reflective mask blank 30 can be obtained in balance with a stress from various films formed on the front main surface.

The back film 23 can include the predetermined thin film described above. That is, the back film 23 of the substrate with a thin film according to the present embodiment is the predetermined thin film containing chromium, and has a predetermined diffracted X-ray spectrum when a diffracted X-ray intensity with respect to the diffraction angle 2θ is measured by an X-ray diffraction method using a CuK_{α} ray for the predetermined thin film. In addition, the back film 23 preferably further contains nitrogen. By inclusion of chromium and nitrogen having a predetermined crystal structure having a predetermined diffracted X-ray spectrum in the back film 23, chemical resistance of the back film 23, particularly resistance to SPM cleaning can be further enhanced, and a predetermined sheet resistance that can be used as a conductive film for an electrostatic chuck can be obtained.

The back film 23 formed of the predetermined thin film can be a uniform film in which the concentrations of elements (for example, a chromium element and a nitrogen element) contained in the thin film are uniform except for a surface layer affected by surface oxidation. In addition, the back film 23 can be an inclined composition film in which the concentration of an element contained in the back film 23 changes in a thickness direction of the back film 23. In addition, the back film 23 can be a layered film including a plurality of layers having a plurality of different compositions as long as the effect of the present embodiment is not impaired.

The substrate with a back film 50 according to the present embodiment can include a base film (for example, a film formed of a material containing chromium, nitrogen, and oxygen) between the back film 23 and the substrate 10. Examples of the material of the base film include CrO, CrON, and the like. Furthermore, an upper layer film may be formed on a surface of the back film 23 opposite to the substrate 10.

The substrate with a back film 50 according to the present embodiment can include, for example, a hydrogen intrusion suppressing film that suppresses intrusion of hydrogen from the substrate 10 (glass substrate) into the back film 23 between the substrate 10 and the back film 23. The presence of the hydrogen intrusion suppressing film can suppress incorporation of hydrogen into the back film 23, and can suppress an increase in a compressive stress of the back film 23.

A material of the hydrogen intrusion suppressing film may be any type of material as long as the material hardly transmits hydrogen and can suppress intrusion of hydrogen from the substrate 10 (glass substrate) into the back film 23. Specific examples of the material of the hydrogen intrusion suppressing film include Si, SiO₂, SiON, SiCO, SiCON, SiBO, SiBON, Cr, CrN, CrO, CrON, CrC, CrCN, CrCO, CrCON, Mo, MoSi, MoSiN, MoSiO, MoSiCO, MoSiON, MoSiCON, TaO, TaON, and the like.

The hydrogen intrusion suppressing film can be a single layer made of these materials, or may be a multilayer or an inclined composition film. CrO can be used as a material of the hydrogen intrusion suppressing film.

The material for forming the back film 23 can further contain an element other than chromium and nitrogen as long as the effect of the present embodiment is not impaired. Examples of the element other than chromium and nitrogen include Ag, Au, Cu, Al, Mg, W, Co, and the like which are highly conductive metals.

Patent Document 3 describes a method for correcting an error of a photolithography mask with a laser beam. When the technique described in Patent Document 3 is applied to the reflective mask 40, it is conceivable to irradiate the reflective mask 40 with a laser beam from a back main surface of the substrate 10. However, since the back film 23 is disposed on the back main surface of the substrate 10 of the reflective mask 40, there arises a problem that the laser beam hardly passes through the reflective mask 40. When chromium is used as a material of the thin film, the thin film has a relatively high visible light transmittance at a predetermined wavelength. Therefore, when the thin film containing chromium is used as the back film 23 (conductive film) of the reflective mask 40, the defect correction as described in Patent Document 3 can be performed by irradiating the reflective mask 40 with predetermined light from the back main surface.

As the film thickness of the back film 23, an appropriate film thickness can be selected in relation to transmittance in light having a wavelength of 532 nm and electrical conductivity. For example, when the electrical conductivity of a material is high, the film thickness can be made thin, and the transmittance can be increased. The film thickness of the back film 23 of the substrate with a back film 50 according to the present embodiment using chromium as a material of the thin film is preferably 10 nm or more and 50 nm or less. When the back film 23 has a predetermined film thickness, the back film 23 having more appropriate transmittance and conductivity can be obtained.

The transmittance of the back film 23 at a wavelength of 532 nm is preferably 10% or more, more preferably 20% or more, and still more preferably 25% or more. The transmittance at a wavelength of 632 nm is preferably 25% or more. When the transmittance of light having a predetermined wavelength of the back film 23 of the substrate with a back film 50 is in a predetermined range, it is possible to obtain the reflective mask 40 capable of correcting a positional deviation of the reflective mask 40 from a side of the back main surface with a laser beam or the like.

Note that the transmittance in the present embodiment is obtained by irradiating the substrate with a back film 50 including the back film 23 with light having a wavelength of 532 nm from the back film 23 side and measuring transmitted light that has passed through the back film 23 and the substrate 10.

The back film 23 preferably has a film reduction amount of 1 nm or less when SPM cleaning is performed once. As a result, in a process of manufacturing the reflective mask blank 30, the reflective mask 40, and/or a semiconductor device, even when wet cleaning using an acidic aqueous solution (chemical solution) such as SPM cleaning is performed, sheet resistance, mechanical strength, and/or transmittance, and the like required for the back film 23 are not impaired.

Note that the SPM cleaning is a cleaning method using H₂SO₄ and H₂O₂, and refers to cleaning performed using a cleaning liquid in which a ratio of H₂SO₄:H₂O₂ is 1:1 to 5:1, for example, under conditions of a treatment time of about 10 minutes at a temperature of 80 to 150° C.

Conditions of the SPM cleaning serving as a criterion for determining cleaning resistance in the present embodiment are as follows.

| | |
|---|---|
| Cleaning liquid | H₂SO₄:H₂O₂ = 2:1 (weight ratio) |
| Cleaning temperature | 120° C. |
| Cleaning time | 10 minutes |

In addition, a pattern transfer device for manufacturing a semiconductor device usually includes an electrostatic chuck for fixing the reflective mask 40 to be mounted on a stage. The back film 23 (conductive film) formed on a back main surface of the reflective mask 40 is fixed to the stage of the pattern transfer device by the electrostatic chuck.

The surface roughness of the back film 23 is preferably 0.6 nm or less, and more preferably 0.4 nm or less in terms of a root mean square roughness (Rms) obtained by measuring a region of 1 μm×1 μm with an atomic force microscope. When the surface of the back film 23 has the predetermined root mean square roughness (Rms), generation of particles due to rubbing between the electrostatic chuck and the back film 23 can be prevented.

In addition, in the pattern transfer device, when a moving speed of the stage on which the reflective mask 40 is mounted is increased to increase production efficiency, a further load is applied to the back film 23. Therefore, the back film 23 desirably has a higher mechanical strength. The mechanical strength of the back film 23 can be evaluated by measuring a crack generation load of the substrate with a back film 50. The mechanical strength is required to be 300 mN or more in terms of a value of a crack generation load. The mechanical strength is preferably 600 mN or more, and more preferably more than 1000 mN in terms of a value of a crack generation load. When the crack generation load is in a predetermined range, it can be said that the back film 23 has a mechanical strength required as the back film 23 for an electrostatic chuck.

### [Reflective Mask Blank 30]

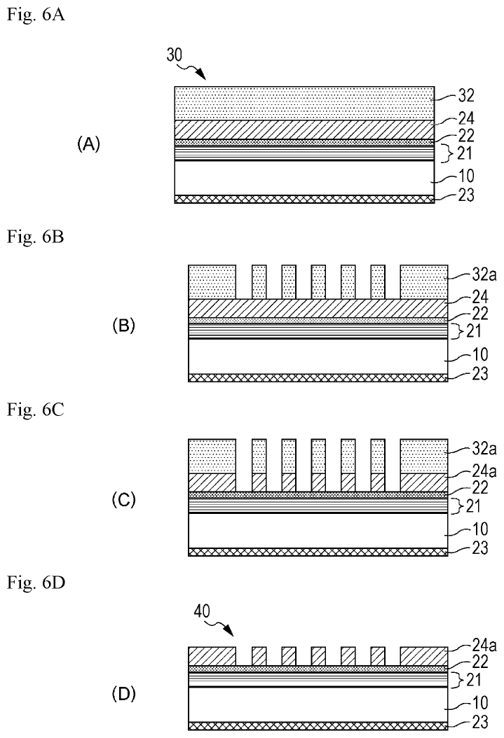

Next, the reflective mask blank 30 according to the present embodiment will be described. FIG. 3 is a schematic diagram illustrating an example of the reflective mask blank 30 according to the present embodiment. The reflective mask blank 30 according to the present embodiment has a structure including the pattern forming thin film 24 on the multilayer reflective film 21 of the substrate with a multilayer reflective film 20 described above or on the protective film 22, and further including the back film 23 on the back main surface. The reflective mask blank 30 can further have the etching mask film 25 and/or a resist film 32 on the pattern forming thin film 24 (see FIGS. 5 and 6A). At least one of the back film 23 and the pattern forming thin film 24 of the reflective mask blank 30 according to the present embodiment is the predetermined thin film described above.

### <Pattern Forming Thin Film 24>

The reflective mask blank 30 has the pattern forming thin film 24 (also referred to as an “absorber film”) on the substrate with a multilayer reflective film 20 described above. That is, the pattern forming thin film 24 is formed on the multilayer reflective film 21 (on the protective film 22 when protective film 22 is formed). A basic function of the pattern forming thin film 24 is to absorb EUV light. The pattern forming thin film 24 may be the pattern forming thin film 24 for the purpose of absorbing EUV light, or may be the pattern forming thin film 24 having a phase shift function in consideration of a phase difference of EUV light. The pattern forming thin film 24 having a phase shift function absorbs EUV light and partially reflects the EUV light to shift a phase. That is, in the reflective mask 40 in which the pattern forming thin film 24 having a phase shift function is patterned, a portion where the pattern forming thin film 24 is formed reflects a part of light at a level that does not adversely affect pattern transfer while absorbing and attenuating EUV light. In addition, in a region (field portion) where the pattern forming thin film 24 is not formed, EUV light is reflected from the multilayer reflective film 21 via the protective film 22. Therefore, there is a desired phase difference between the reflected light from the pattern forming thin film 24 having a phase shift function and the reflected light from the field portion. The pattern forming thin film 24 having a phase shift function is formed such that a phase difference between the reflected light from the pattern forming thin film 24 and the reflected light from the multilayer reflective film 21 is 170 degrees to 190 degrees. Beams of the light having a reversed phase difference around 180 degrees interfere with each other at a pattern edge portion, and an image contrast of a projected optical image is thereby improved. As the image contrast is improved, resolution is increased, and various exposure-related margins such as an exposure margin and a focus margin can be increased.

The pattern forming thin film 24 may be a single-layer film or a multilayer film formed of a plurality of films (for example, a lower layer pattern forming thin film and an upper layer pattern forming thin film). In a case of the single layer film, the number of steps at the time of manufacturing the mask blank can be reduced and production efficiency is increased. In a case of the multilayer film, an optical constant and film thickness of an upper layer pattern forming thin film can be appropriately set such that the upper layer pattern forming thin film serves as an antireflection film at the time of mask pattern defect inspection using light. This improves inspection sensitivity at the time of mask pattern defect inspection using light. In addition, when a film to which oxygen (O), nitrogen (N), and the like that improve oxidation resistance are added is used as the upper layer pattern forming thin film, temporal stability is improved. As described above, when the pattern forming thin film 24 is a multilayer film, various functions can be added thereto. In a case where the pattern forming thin film 24 is the pattern forming thin film 24 having a phase shift function, when the pattern forming thin film 24 is a multilayer film, a range of adjustment on an optical surface can be increased, and therefore a desired reflectance can be easily obtained.

A material of the pattern forming thin film 24 is not particularly limited as long as the material has a function of absorbing EUV light and can be processed by etching or the like (preferably, can be etched by dry etching of a chlorine (Cl) and/or fluorine (F)-based gas). As a material having such a function, a tantalum (Ta) simple substance or a material containing Ta can be preferably used.

Examples of the material containing Ta include a material containing Ta and B, a material containing Ta and N, a material containing Ta, B, and at least one of O and N, a material containing Ta and Si, a material containing Ta, Si, and N, a material containing Ta and Ge, a material containing Ta, Ge, and N, a material containing Ta and Pd, a material containing Ta and Ru, a material containing Ta and Ti, and the like.

The pattern forming thin film 24 can be formed of, for example, a material containing at least one selected from the group consisting of a Ni simple substance, a material containing Ni, a Cr simple substance, a material containing Cr, a Ru simple substance, a material containing Ru, a Pd simple substance, a material containing Pd, a Mo simple substance, and a material containing Mo.

The pattern forming thin film 24 can include the predetermined thin film described above. That is, the pattern forming thin film 24 according to the present embodiment is the predetermined thin film containing chromium (Cr), and can have a predetermined diffracted X-ray spectrum when a diffracted X-ray intensity with respect to the diffraction angle 2θ is measured by an X-ray diffraction method using a CuK_{α} ray for the predetermined thin film. In addition, when the pattern forming thin film 24 is the predetermined thin film, the pattern forming thin film 24 preferably further contains nitrogen (N). By inclusion of chromium (Cr) and nitrogen (N) having a predetermined crystal structure having a predetermined diffracted X-ray spectrum in the pattern forming thin film 24, chemical resistance of the pattern forming thin film 24, particularly resistance to SPM cleaning can be further enhanced.

In order to appropriately absorb EUV light, the pattern forming thin film 24 preferably has a thickness of 30 nm to 100 nm.

The pattern forming thin film 24 can be formed by a known method, for example, a magnetron sputtering method, an ion beam sputtering method, or the like.

### <Etching Mask Film 25>

The etching mask film 25 may be formed on the pattern forming thin film 24. As a material of the etching mask film 25, a material having a high etching selective ratio of the pattern forming thin film 24 to the etching mask film 25 is used. Here, the expression of “an etching selective ratio of B to A” means a ratio of an etching rate of B that is a layer desired to be etched to an etching rate of A that is a layer not desired to be etched (layer to serve as a mask). Specifically, “an etching selective ratio of B to A” is specified by a formula of “etching selective ratio of B to A =etching rate of B/etching rate of A”. In addition, the expression of “high selective ratio” means that a value of the selective ratio defined above is large as compared with that of an object for comparison. The etching selective ratio of the pattern forming thin film 24 to the etching mask film 25 is preferably 1.5 or more, and more preferably 3 or more.

Examples of the material having a high etching selective ratio of the pattern forming thin film 24 to the etching mask film 25 include a chromium material and a chromium compound material. Therefore, when the pattern forming thin film 24 is etched with a fluorine-based gas, a chromium material and a chromium compound material can be used. Examples of the chromium compound include a material containing Cr and at least one element selected from N, O, C, and H. In addition, when the pattern forming thin film 24 is etched with a chlorine-based gas substantially containing no oxygen, a silicon material or a silicon compound material can be used. Examples of the silicon compound include a material containing Si and at least one element selected from N, O, C and H and a material such as metallic silicon containing a metal in silicon or a silicon compound (metal silicide) or a metal silicon compound (metal silicide compound). Examples of the metal silicon compound include a material containing a metal, Si, and at least one element selected from N, O, C, and H.

The film thickness of the etching mask film 25 is desirably 3 nm or more from a viewpoint of obtaining a function as an etching mask for accurately forming a transfer pattern on the pattern forming thin film 24. In addition, the film thickness of the etching mask film 25 is desirably 15 nm or less from a viewpoint of reducing the film thickness of the resist film 32.

The etching mask film 25 can include the predetermined thin film described above. That is, the etching mask film 25 according to the present embodiment is the predetermined thin film containing chromium (Cr), and can have a predetermined diffracted X-ray spectrum when a diffracted X-ray intensity with respect to the diffraction angle 2θ is measured by an X-ray diffraction method using a CuK_{α} ray for the predetermined thin film. In addition, when the etching mask film 25 is the predetermined thin film, the etching mask film 25 preferably further contains nitrogen (N). By inclusion of chromium (Cr) and nitrogen (N) having a predetermined crystal structure having a predetermined diffracted X-ray spectrum in the etching mask film 25, chemical resistance of the etching mask film 25, particularly resistance to SPM cleaning can be further enhanced.

### [Reflective Mask 40]

Next, the reflective mask 40 according to the present embodiment will be described below. FIG. 4 is a schematic diagram illustrating the reflective mask 40 according to the present embodiment. In the reflective mask 40 according to the present embodiment, a transfer pattern is formed on the pattern forming thin film 24 of the reflective mask blank 30.

The reflective mask 40 according to the present embodiment has a structure in which the pattern forming thin film 24 in the above reflective mask blank 30 is patterned to form the thin film pattern 24a of the pattern forming thin film 24 on the multilayer reflective film 21 or the protective film 22. When the reflective mask 40 according to the present embodiment is exposed with exposure light such as EUV light, the exposure light is absorbed in a portion where the pattern forming thin film 24 is present on a surface of the reflective mask 40, and the exposure light is reflected by the exposed protective film 22 and multilayer reflective film 21 in the other portions where the pattern forming thin film 24 has been removed. As a result, the reflective mask 40 can be used as the reflective mask 40 for lithography.

By inclusion of the thin film pattern 24a on the multilayer reflective film 21 (or on the protective film 22) in the reflective mask 40 according to the present embodiment, a predetermined pattern can be transferred onto a transferred object using EUV light.

The reflective mask 40 according to the present embodiment includes the back film 23 and/or the pattern forming thin film 24 having excellent chemical resistance.

Therefore, even if the reflective mask 40 according to the present embodiment is repeatedly cleaned using a chemical such as a chemical solution, deterioration of the reflective mask 40 can be suppressed. Therefore, it can be said that the reflective mask 40 of the present disclosure can have a highly accurate transfer pattern.

### [Method for Manufacturing a Semiconductor Device]

A method for manufacturing a semiconductor device according to the present embodiment includes a step of exposing and transferring a transfer pattern onto a resist film on a semiconductor substrate using the reflective mask 40 according to the present embodiment. That is, a transfer pattern such as a circuit pattern based on the thin film pattern 24a of the reflective mask 40 is transferred onto a resist film formed on a transferred object such as a semiconductor substrate by a lithography process using the reflective mask 40 described above and an exposure device. Thereafter, through various other steps, it is possible to manufacture a semiconductor device in which various transfer patterns and the like are formed on a transferred object such as a semiconductor substrate.

According to the method for manufacturing a semiconductor device according to the present embodiment, the reflective mask 40 having the thin film pattern 24a of the back film 23 and/or the pattern forming thin film 24 having excellent chemical resistance can be used for manufacturing a semiconductor device. Even if the reflective mask 40 is repeatedly cleaned using a chemical such as a chemical solution (for example, a sulfuric acid and hydrogen peroxide mixture in a case of SPM cleaning), deterioration of the back film 23 and/or the thin film pattern 24a of the reflective mask 40 can be suppressed. Therefore, even when the reflective mask 40 is repeatedly used, a semiconductor device having a fine and highly accurate transfer pattern can be manufactured.

### EXAMPLES

Hereinafter, Examples will be described with reference to the drawings. However, the present disclosure is not limited to these Examples.

### Example 1

First, a substrate with a back film 50, which is a substrate with a thin film of Example 1, will be described.

A substrate 10 for manufacturing the substrate with a back film 50 of Example 1 was prepared as follows. That is, an SiO₂-TiO₂-based glass substrate that is a low thermal expansion glass substrate having a 6025 size (approximately 152 mm×152 mm×6.35 mm) in which both main surfaces that are a first main surface and a second main surface were polished was prepared as the substrate 10. The main surfaces were subjected to polishing including a rough polishing step, a precision polishing step, a local processing step, and a touch polishing step such that the main surfaces were flat and smooth.

A base film (not illustrated) formed of a CrON film was formed on the second main surface (back main surface) of the SiO₂-TiO₂-based glass substrate (mask blank substrate 10) of Example 1, and a back film 23 formed of a CrN film was formed on the base film. The CrON film (base film) was formed so as to have a film thickness of 15 nm in a mixed gas atmosphere of an Ar gas, a N₂ gas, and an O₂ gas using a Cr target by a reactive sputtering method (DC magnetron sputtering method). Subsequently, the back film 23 formed of a CrN film was formed on the base film. The CrN film (back film 23) was formed so as to have a film thickness of 180 nm in a mixed gas atmosphere of an Ar gas and a N₂ gas using a Cr target by a reactive sputtering method (DC magnetron sputtering method). When the composition (atomic %) of the CrN film was measured by X-ray photoelectron spectroscopy (XPS method), the atomic ratio of chromium (Cr) was 91 atomic %, and the atomic ratio of nitrogen (N) was 9 atomic %.

For the back film 23 of Example 1, a diffracted X-ray intensity with respect to the diffraction angle 2θ was measured by an X-ray diffraction method using a CuK_{α} ray.

As an X-ray diffractometer, a SmartLab manufactured by Rigaku Corporation was used. The diffracted X-ray spectrum was measured using a Cu—K_{α} ray source in a range where the diffraction angle 2θ was 30 degrees to 70 degrees under conditions of a sampling width of 0.01 degrees and a scan speed of 2 degrees/minute. The back film 23 was irradiated with an X-ray generated using the Cu—K_{α} ray source, and a diffracted X-ray intensity at the diffraction angle 2θ was measured to obtain a diffracted X-ray spectrum. From the obtained diffracted X-ray spectrum, presence or absence of a peak was determined in a range where the diffraction angle 2θ is 56 degrees or more and 60 degrees or less, in a range where the diffraction angle 2θ is 41 degrees or more and 47 degrees or less, and in a range where the diffraction angle 2θ is 35 degrees or more and 38 degrees or less. Note that as for the determination of presence or absence of a peak, when the height of a peak obtained by subtracting a background from a measured diffracted X-ray spectrum was twice or more the magnitude of a background noise (noise width) around the peak, it was determined that there was a peak. Note that no peak of the CrON film (base film) was observed in the obtained diffracted X-ray spectrum. Therefore, it can be said that the diffracted X-ray spectrum obtained by the measurement is the diffracted X-ray spectrum of the CrN film (back film 23). The same applies to diffracted X-ray spectra of Comparative Examples 1 and 2.

FIG. 7 illustrates the diffracted X-ray spectrum of Example 1. As is clear from FIG. 7, in the back film 23 of Example 1, there was a peak in a range where the diffraction angle 2θ is 56 degrees or more and 60 degrees or less and in a range where the diffraction angle 2θ is 41 degrees or more and 47 degrees or less, but there was no peak in a range where the diffraction angle 2θ is 35 degrees or more and 38 degrees or less. Table 1 illustrates presence or absence of a peak in each range of the diffraction angle 2θ in Example 1.

The substrate with a back film 50 of Example 1 was manufactured as described above.

Here, an evaluation thin film of Example 1 was prepared in which a CrN film was formed on the substrate 10 under the same film forming conditions as described above. Sheet resistance (IVA) and a film reduction amount (nm) by SPM cleaning were measured for the obtained evaluation thin film of Example 1. Table 1 illustrates measurement results.

The film reduction amount (nm) of the substrate with a back film 50 of Example 1 by SPM cleaning was calculated by measuring the film thickness before and after SPM cleaning was performed once under the following cleaning conditions.

| | |
|---|---|
| Cleaning liquid | H₂SO₄:H₂O₂ = 2:1 (weight ratio) |
| Cleaning temperature | 120° C. |
| Cleaning time | 10 minutes |

As described above, the substrate with a back film 50 of Example 1 was manufactured and evaluated.

### Comparative Example 1

A substrate with a back film 50 of Comparative Example 1 has a base film formed of a CrON film and a back film 23 formed of a CrN film as in Example 1. However, the film forming conditions (flow rate of a N₂ gas) and the atomic ratio of the CrN film of the back film 23 of Comparative Example 1 are different from those of Example 1. The substrate with a back film 50 of Comparative Example 1 was manufactured in a similar manner to Example 1 except for these. The CrN film (back film 23) of Comparative Example 1 was formed so as to have a film thickness of 180 nm. When the composition (atomic %) of the CrN film was measured by X-ray photoelectron spectroscopy (XPS method), the atomic ratio of chromium (Cr) was 57 atomic %, and the atomic ratio of nitrogen (N) was 43 atomic %.

For the back film 23 of Comparative Example 1, a diffracted X-ray intensity with respect to the diffraction angle 2θ was measured by an X-ray diffraction method using a CuK, ray in a similar manner to Example 1 FIG. 7 illustrates a diffracted X-ray spectrum of Comparative Example 1. As is clear from FIG. 7, in the back film 23 of Comparative Example 1, there was a peak in a range where the diffraction angle 2θ is 41 degrees or more and 47 degrees or less and in a range where the diffraction angle 2θ is 35 degrees or more and 38 degrees or less, but there was no peak in a range where the diffraction angle 2θ is 56 degrees or more and 60 degrees or less. Table 1 illustrates presence or absence of a peak in each range of the diffraction angle 2θ in Comparative Example 1.

Here, an evaluation thin film of Comparative Example 1 was prepared in which a CrN film was formed on the substrate 10 under the same film forming conditions as Comparative Example 1 described above. Sheet resistance (Ω/A) and a film reduction amount (nm) by SPM cleaning were measured for Comparative Example 1 in a similar manner to Example 1 Table 1 illustrates measurement results.

As described above, the substrate with a back film 50 of Comparative Example 1 was manufactured and evaluated.

### Comparative Example 2

A substrate with a back film 50 of Comparative Example 2 has a base film of a CrON film and a back film 23 of a CrN film as in Example 1. However, the film forming conditions (flow rate of a N₂ gas) and the atomic ratio of the CrN film of the back film 23 of Comparative Example 2 are different from those of Example 1 and Comparative Example 1. The substrate with a back film 50 of Comparative Example 2 was manufactured in a similar manner to Example 1 except for these. The CrN film (back film 23) of Comparative Example 2 was formed so as to have a film thickness of 180 nm. When the composition (atomic %) of the CrN film was measured by X-ray photoelectron spectroscopy (XPS method), the atomic ratio of chromium (Cr) was 90 atomic %, and the atomic ratio of nitrogen (N) was 10 atomic %.

For the back film 23 of Comparative Example 2, a diffracted X-ray intensity with respect to the diffraction angle 2θ was measured by an X-ray diffraction method using a CuK_{α} ray in a similar manner to Example 1 FIG. 8 illustrates a diffracted X-ray spectrum of Comparative Example 2. As is clear from FIG. 8, in the back film 23 of Comparative Example 2, there was no peak in any of a range where the diffraction angle 2θ is 56 degrees or more and 60 degrees or less, a range where the diffraction angle 2θ is 41 degrees or more and 47 degrees or less, and a range where the diffraction angle 2θ is 35 degrees or more and 38 degrees or less. This indicates that the back film 23 of Comparative Example 2 is a thin film having an amorphous structure. Table 1 illustrates presence or absence of a peak in each range of the diffraction angle 2θ in Comparative Example 2.

Here, an evaluation thin film of Comparative Example 2 was prepared in which a CrN film was formed on the substrate 10 under the same film forming conditions as Comparative Example 2 described above. Sheet resistance (Ω/A) and a film reduction amount (nm) by SPM cleaning were measured for Comparative Example 2 in a similar manner to Example 1 Table 1 illustrates measurement results.

As described above, the substrate with a back film 50 of Comparative Example 2 was manufactured and evaluated.

### [Comparison Between Example 1 and Comparative Examples 1 and 2]

As illustrated in Table 1, the sheet resistance of the back film 23 of the substrate with a back film 50 of Example 1 was 150 Ω/A or less, which was a value satisfactory as the back film 23 of the reflective mask 40. In addition, the film reduction amount of the back film 23 of Example 1 by SPM cleaning was 0.1 nm, which was a value satisfactory as the back film 23 of the reflective mask 40.

As illustrated in Table 1, the sheet resistance of the back film 23 of the substrate with a back film 50 of each of Comparative Examples 1 and 2 was 150 Ω/A or less, which was a value satisfactory as the back film 23 of the reflective mask 40. However, the film reduction amount of the back films 23 of each of Comparative Examples 1 and 2 by SPM cleaning was more than 1 nm, which was not a satisfactory value as the back film 23 of the reflective mask 40.

The above result has revealed that the back film 23 having the crystal structure of Example 1 in which a peak is present in a range where the diffraction angle 2θ is 56 degrees or more and 60 degrees or less has excellent chemical resistance.

[Substrate with a Multilayer Reflective Film 20]

Next, a substrate with a multilayer reflective film 20 of Example 1 will be described. By forming a multilayer reflective film 21 and a protective film 22 on the main surface (first main surface) of the substrate 10 opposite to the side on which the back film 23 of the substrate with a back film 50 manufactured as described above was formed, a substrate with a multilayer reflective film 20 was manufactured. Specifically, the substrate with a multilayer reflective film 20 was manufactured as follows.

The multilayer reflective film 21 was formed on the main surface (first main surface) of the substrate 10 opposite to the side on which the back film 23 was formed. The multilayer reflective film 21 formed on the substrate 10 was the periodic multilayer reflective film 21 containing Mo and Si in order to make the multilayer reflective film 21 suitable for EUV light having a wavelength of 13.5 nm. Using a Mo target and a Si target, the multilayer reflective film 21 was formed by alternately building up a Mo layer and a Si layer on the substrate 10 in an Ar gas atmosphere by an ion beam sputtering method. First, a Si film was formed so as to have a thickness of 4.2 nm, and subsequently a Mo film was formed so as to have a thickness of 2.8 nm. This stack of a Si film and a Mo film was counted as one period, and a Si film and a Mo film were built up for 40 periods in a similar manner. Finally, a Si film was formed so as to have a thickness of 4.0 nm to form the multilayer reflective film 21. The number of periods was 40 periods here, but the number of periods is not limited to this number, but may be, for example, 60 periods. In the case of 60 periods, the number of steps is larger than the number of steps in the case of 40 periods, but reflectance for EUV light can be increased.

Subsequently, the protective film 22 formed of a Ru film was formed so as to have a thickness of 2.5 nm in an Ar gas atmosphere by an ion beam sputtering method using a Ru target.

The substrate with a multilayer reflective film 20 of Example 1 was manufactured as described above.

### [Reflective Mask Blank 30]

Next, a reflective mask blank 30 of Example 1 will be described. By forming a pattern forming thin film 24 on the protective film 22 of the substrate with a multilayer reflective film 20 manufactured as described above, the reflective mask blank 30 was manufactured.

The pattern forming thin film 24 was formed on the protective film 22 of the substrate with a multilayer reflective film 20 by a DC magnetron sputtering method.

The pattern forming thin film 24 was the pattern forming thin film 24 of a layered film including two layers of a TaN film as an absorption layer and a TaO film as a low reflection layer. The TaN film was formed as an absorption layer on a surface of the protective film 22 of the substrate with a multilayer reflective film 20 described above by a DC magnetron sputtering method. The TaN film was formed in a mixed gas atmosphere of an Ar gas and a N₂ gas with the substrate with a multilayer reflective film 20 facing a Ta target by a reactive sputtering method. Next, the TaO film (low reflection layer) was further formed on the TaN film by a DC magnetron sputtering method. Similarly to the TaN film, this TaO film was formed in a mixed gas atmosphere of Ar and O₂ with the substrate with a multilayer reflective film 20 facing a Ta target by a reactive sputtering method.

The composition (atomic ratio) of the TaN film was Ta:N=70:30, and the TaN film had a film thickness of 48 nm. The composition (atomic ratio) of the TaO film was Ta:O=35:65, and the TaO film had a film thickness of 11 nm.

As described above, the reflective mask blank 30 of Example 1 was manufactured.

### [Reflective Mask 40]

Next, a reflective mask 40 of Example 1 will be described. The reflective mask 40 was manufactured using the reflective mask blank 30 described above. FIGS. 6A to 6D are schematic cross-sectional diagrams of a main part illustrating a process of preparing the reflective mask 40 from the reflective mask blank 30.

A resist film 32 having a thickness of 150 nm was formed on the pattern forming thin film 24 of the reflective mask blank 30 of Example 1 described above, and the resulting product was used as the reflective mask blank 30 (FIG. 6A). A desired pattern was drawn (exposed) on this resist film 32, and further developed and rinsed to form a predetermined resist pattern 32a (FIG. 6B). Next, the pattern forming thin film 24 was dry-etched using the resist pattern 32a as a mask to form a pattern (thin film pattern) 24a of the pattern forming thin film 24 (FIG. 6C). Note that the TaN film and the TaO film of the pattern forming thin film 24 were both patterned by dry etching using a mixed gas of CF₄ and He.

Thereafter, the resist pattern 32a was removed, for example, by ashing or with a resist stripper liquid. Finally, the same SPM cleaning as the above-described cleaning conditions at the time of measuring the film reduction amount by SPM cleaning was performed. The reflective mask 40 was manufactured as described above (FIG. 6D). Note that a mask defect inspection can be performed as necessary after the wet cleaning, and a mask defect can be corrected appropriately.

As described in the evaluation of the substrate with a back film 50 of Example 1, the substrate with a back film 50 having the back film 23 of Example 1 according to the present embodiment has excellent SPM cleaning resistance. Therefore, the reflective mask 40 having the back film 23 according to the present embodiment also has excellent SPM cleaning resistance. Therefore, even when SPM cleaning is performed on the reflective mask 40, sheet resistance and mechanical strength required for the back film 23 are not impaired. In addition, even when the reflective mask 40 according to the present embodiment is used for manufacturing a semiconductor device, the reflective mask 40 can be fixed by an electrostatic chuck without any problem. Therefore, when the reflective mask 40 according to the present embodiment is used for manufacturing a semiconductor device, it can be said that a semiconductor device having a fine and highly accurate transfer pattern can be manufactured.

The reflective mask 40 prepared in Example 1 was set in an EUV exposure device, and EUV exposure was performed on a wafer on which a film to be processed and a resist film were formed on a semiconductor substrate. Then, this resist film that had been subjected to exposure was developed to form a resist pattern on the semiconductor substrate on which the film to be processed was formed.

This resist pattern was transferred onto a film to be processed by etching, and through various steps such as formation of an insulating film and a conductive film, introduction of a dopant, and annealing, a semiconductor device having desired characteristics could be manufactured.

TABLE 1

| | Peak in range of | Peak in range of | Peak in range of | Sheet | Film reduction |
|---|---|---|---|---|---|
| | 56 degrees ≤ 2θ ≤ | 41 degrees ≤ 2θ ≤ | 35 degrees ≤ 2θ ≤ | resistance | amount (nm) by |
| | 60 degrees | 47 degrees | 38 degrees | (Ω/□) | SPM cleaning |
| Example 1 | Present | Present | Absent | 55 | 0.1 |
| Comparative | Absent | Present | Present | 138 | 1.1 |
| Example 1 | | | | | |
| Comparative | Absent | Absent | Absent | 53 | 1.3 |
| Example 2 | | | | | |

### REFERENCE SIGNS LIST

10 Mask blank substrate
20 Substrate with a multilayer reflective film
21 Multilayer reflective film
22 Protective film
23 Back film
24 Pattern forming thin film
24a Thin film pattern
25 Etching mask film
30 Reflective mask blank
32 Resist film
32a Resist pattern
40 Reflective mask
50 Substrate with a back film

1. A substrate with a thin film comprising:
a substrate; and
a thin film on at least one of two main surfaces of the substrate, wherein:
the thin film comprises chromium; and
a diffracted X-ray intensity of the thin film, with respect to a diffraction angle 2θ and as measured by an X-ray diffraction method using a CuK_{α} ray, has a peak in a range where the diffraction angle 2θ is 56 degrees or more and 60 degrees or less.

2. The substrate with a thin film according to claim 1, wherein the diffracted X-ray intensity of the thin film has a peak in a range where the diffraction angle 2θ is 41 degrees or more and 47 degrees or less.

3. The substrate with a thin film according to claim 1, wherein the diffracted X-ray intensity of the thin film has no peak in a range where the diffraction angle 2θ is 35 degrees or more and 38 degrees or less.

4. The substrate with a thin film according claim 1, wherein the thin film further comprises nitrogen.

5. A substrate with a multilayer reflective film comprising:
a substrate; and
a multilayer reflective film on one of two main surfaces of the substrate, wherein:
the substrate comprises a back film on the other main surface of the substrate;
the back film comprises chromium; and
a diffracted X-ray intensity of the back film, with respect to a diffraction angle 2θ and as measured by an X-ray diffraction method using a CuK_{α} ray, has a peak in a range where the diffraction angle 2θ is 56 degrees or more and 60 degrees or less.

6. The substrate with a multilayer reflective film according to claim 5, wherein the diffracted X-ray intensity of the back film has a peak in a range where the diffraction angle 2θ is 41 degrees or more and 47 degrees or less.

7. The substrate with a multilayer reflective film according to claim 5, wherein the diffracted X-ray intensity of the back film has no peak in a range where the diffraction angle 2θ is 35 degrees or more and 38 degrees or less.

8. The substrate with a multilayer reflective film according to claim 5, wherein the back film further comprises nitrogen.

9. A reflective mask blank comprising a structure in which a multilayer reflective film and a pattern-forming thin film are layered in this order on one of two main surfaces of the substrate, wherein:
the substrate comprises a back film on the other main surface of the substrate;
the back film comprises chromium; and
a diffracted X-ray intensity of the back film, with respect to a diffraction angle 2θ and as measured by an X-ray diffraction method using a CuK_{α} ray, has a peak in a range where the diffraction angle 2θ is 56 degrees or more and 60 degrees or less.

10. The reflective mask blank according to claim 9, wherein the diffracted X-ray intensity of the back film has a peak in a range where the diffraction angle 2θ is 41 degrees or more and 47 degrees or less.

11. The reflective mask blank according to claim 9, wherein the diffracted X-ray intensity of the back film has no peak in a range where the diffraction angle 2θ is 35 degrees or more and 38 degrees or less.

12. The reflective mask blank according to claim 9, wherein the back film further comprises nitrogen.

13. A reflective mask comprising a transfer pattern formed on the pattern-forming thin film of the reflective mask blank according to claim 9.

14. A method for manufacturing a semiconductor device, the method comprising using the reflective mask according to claim 13 to expose and transfer a transfer pattern to a resist film on a semiconductor substrate.

15. The substrate with a thin film according to claim 1, wherein a height obtained by subtracting a background of the diffracted X-ray intensity from the peak is at least twice a magnitude of a background noise of the diffracted X-ray intensity around the peak.

16. The substrate with a multilayer reflective film according to claim 5, wherein a height obtained by subtracting a background of the diffracted X-ray intensity from the peak is at least twice a magnitude of a background noise of the diffracted X-ray intensity around the peak.

17. The reflective mask blank according to claim 9, wherein a height obtained by subtracting a background of the diffracted X-ray intensity from the peak is at least twice a magnitude of a background noise of the diffracted X-ray intensity around the peak.

18. The substrate with a thin film according to claim 3, wherein a peak is defined as a value of the diffracted X-ray intensity for which a height obtained by subtracting a background from the value is at least twice the magnitude of a background noise around the value.

19. The substrate with a multilayer reflective film according to claim 7, wherein a peak is defined as a value of the diffracted X-ray intensity for which a height obtained by subtracting a background from the value is at least twice the magnitude of a background noise around the value.

20. The reflective mask blank according to claim 11, wherein a peak is defined as a value of the diffracted X-ray intensity for which a height obtained by subtracting a background from the value is at least twice the magnitude of a background noise around the value.
